(19) United States
(12) Patent Application Publication
(10) Pub. No.: US 2025/0157902 A1
(43) Pub. Date: May 15, 2025

(54) SEMICONDUCTOR PACKAGE INCLUDING A CONDUCTIVE PILLAR

(71) Applicant: SAMSUNG ELECTRONICS CO., LTD., SUWON-SI (KR)

(72) Inventors: Junghoon KANG, Suwon-si (KR); Kiju LEE, Suwon-si (KR)

(21) Appl. No.: 18/938,811

(22) Filed: Nov. 6, 2024

(30) Foreign Application Priority Data
Nov. 10, 2023 (KR) 10-2023-0155716

(51) Int. Cl. H01L 23/498; H01L 21/48; H01L 23/31; H01L 23/538

(52) U.S. Cl. CPC H01L 23/49811; H01L 23/49866; H01L 23/5385; H01L 21/4853; H01L 23/3135

(57) ABSTRACT

A semiconductor package includes: a first redistribution structure; a second redistribution structure arranged on the first redistribution structure; a first conductive pillar arranged spaced apart from the second redistribution structure and arranged on the first redistribution structure; a first chip arranged on the second redistribution structure; a first molding member covering the first chip and disposed on the second redistribution structure; a third redistribution structure arranged on the first molding member; a second chip arranged on the third redistribution structure; a second molding member covering the first conductive pillar and the first molding member; and a fourth redistribution structure arranged on the second molding member, wherein a first film is arranged on a first surface of the first conductive pillar, and the first film includes tin (Sn).

### CROSS-REFERENCE TO RELATED APPLICATION

This application claims priority under 35 U.S.C. § 119 to Korean Patent Application No. 10-2023-0155716, filed on Nov. 10, 2023, in the Korean Intellectual Property Office, the disclosure of which is incorporated by reference herein in its entirety.

### TECHNICAL FIELD

Embodiments of the present inventive concept relate to a semiconductor package, and more particularly, to a semiconductor package including a conductive pillar.

### DISCUSSION OF THE RELATED ART

As the storage capacity of semiconductor devices increases, it has been desired that semiconductor packages including semiconductor devices become thinner and lighter. Recently, research is being performed to increase the operation speed of semiconductor chips and structural reliability of semiconductor packages. In miniaturized semiconductor packages, it is desirable for an aspect ratio of a conductive pillar to be higher.

### SUMMARY

According to embodiments of the present inventive concept, a semiconductor package includes: a first redistribution structure; a second redistribution structure arranged on the first redistribution structure; a first conductive pillar arranged spaced apart from the second redistribution structure and arranged on the first redistribution structure; a first chip arranged on the second redistribution structure; a first molding member covering the first chip and disposed on the second redistribution structure; a third redistribution structure arranged on the first molding member; a second chip arranged on the third redistribution structure; a second molding member covering the first conductive pillar and the first molding member; and a fourth redistribution structure arranged on the second molding member, wherein a first film is arranged on a first surface of the first conductive pillar, and the first film includes tin (Sn).

According to embodiments of the present inventive concept, a semiconductor package includes: a first redistribution structure including an upper surface, a lower surface opposite to the upper surface, and a first upper pad disposed at the upper surface; a second redistribution structure arranged on the first redistribution structure; a first conductive pillar arranged spaced apart from the second redistribution structure and on the first upper pad of the first redistribution structure; a plurality of solder balls arranged between the first upper pad and the first conductive pillar; a first chip arranged on the second redistribution structure; a first molding member covering the first chip and disposed on the second redistribution structure; a third redistribution structure arranged on the first molding member; a second chip arranged on the third redistribution structure; a second molding member covering the first conductive pillar and the first molding member; and a fourth redistribution structure arranged on the second molding member.

According to embodiments of the present inventive concept, a semiconductor package includes: a first redistribution structure including an upper surface, a lower surface opposite to the upper surface, and a first upper pad disposed in the first redistribution structure; a second redistribution structure arranged on the first redistribution structure; a first bump arranged between the first redistribution structure and the second redistribution structure; a first conductive pillar arranged spaced apart from the second redistribution structure and on the first upper pad of the first redistribution structure; a first film covering a lower surface and a lateral surface of the first conductive pillar; a first chip arranged on the second redistribution structure; a second conductive pillar arranged spaced apart from the first chip and disposed on the second redistribution structure; a first molding member covering the first chip and the second conductive pillar and disposed on the second redistribution structure; a third redistribution structure arranged on the first molding member; a second chip arranged on the third redistribution structure and having a size greater than a size of the first chip; a second molding member covering the first conductive pillar and the first molding member; and a fourth redistribution structure arranged on the second molding member, wherein a thickness of the first film is in a range from about 1 μm to about 3 μm, a melting point of the first film is lower than a melting point of the first conductive pillar, and an aspect ratio of the first conductive pillar is in a range from 1:2 to 1:5.

### BRIEF DESCRIPTION OF THE DRAWINGS

The above and other aspects of the present inventive concept will become more apparent by describing in detail embodiments thereof, with reference to the accompanying drawings, in which:

FIG. 1A is a cross-sectional view along an X-Z plane, schematically illustrating a semiconductor package according to embodiments of the present inventive concept;

FIG. 1B is an enlarged view illustrating part AA of FIG. 1A;

FIG. 2A is a cross-sectional view along an X-Z plane, schematically illustrating a semiconductor package according to some embodiments;

FIG. 2B is an enlarged view illustrating part BB of FIG. 2A;

FIG. 3A is a cross-sectional view along an X-Z plane, schematically illustrating a semiconductor package according to embodiments of the present inventive concept;

FIG. 3B is an enlarged view illustrating part CC of FIG. 3A;

FIG. 4 is a cross-sectional view along an X-Z plane, schematically illustrating a semiconductor package according to embodiments of the present inventive concept; and

FIGS. 5, 6A, 6B, 6C, 7A, 7B, 7C, 8A, 8B, and 8C are schematic diagrams illustrating a method of manufacturing a semiconductor package according to embodiments of the present inventive concept.

### DETAILED DESCRIPTION OF THE EMBODIMENTS

Hereinafter, embodiments of the present inventive concept are described in detail with reference to the accompanying drawings. In the drawings and the specification, like reference numerals may denote like components, and any redundant description thereof will be omitted or briefly discussed.

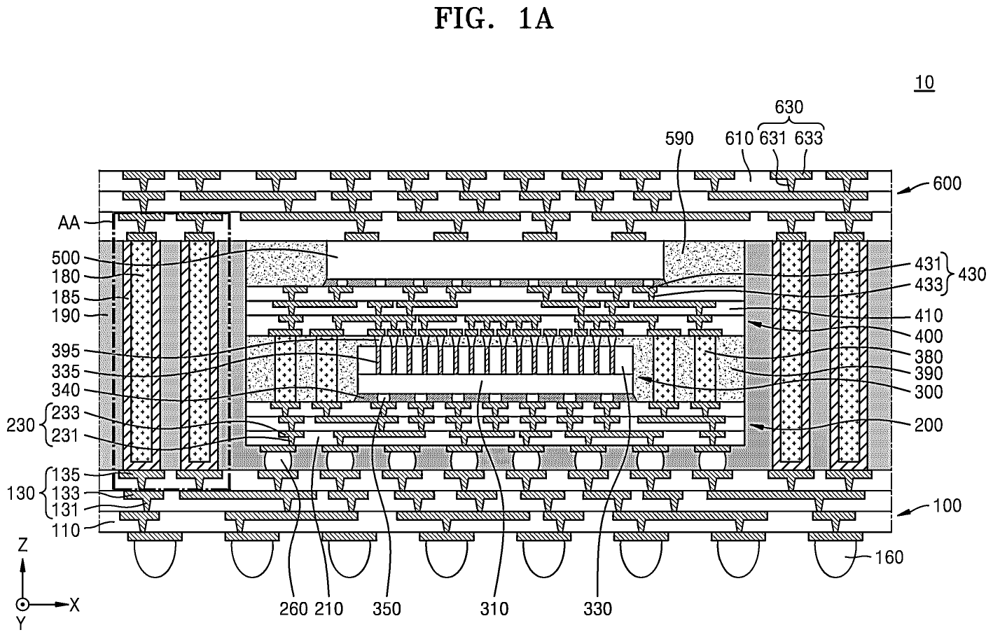

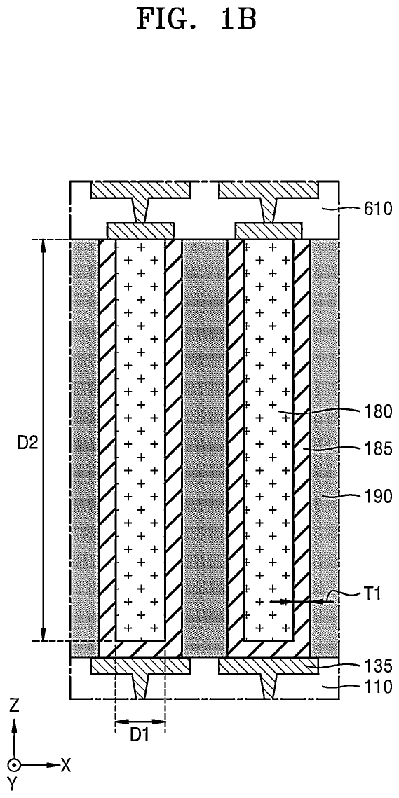

FIG. 1A is a cross-sectional view along an X-Z plane, schematically illustrating a semiconductor package according to embodiments of the present inventive concept. FIG. 1B is an enlarged view illustrating part AA of FIG. 1A.

Referring to FIGS. 1A and 1B, a semiconductor package 10 may include a first redistribution structure 100, a second redistribution structure 200, a first conductive pillar 180, a first chip 300, a third redistribution structure 400, a second chip 500, a first molding member 390, a second molding member 190, and a fourth redistribution structure 600.

The first redistribution structure 100 may be electrically connected to each of the first conductive pillar 180, the second redistribution structure 200, and an external connection terminal 160, and may include a first redistribution pattern 130 and a first redistribution insulating layer 110 covering the first redistribution pattern 130. In embodiments of the present inventive concept, at least one of an upper surface and/or a lower surface of the first redistribution structure 100 may have a plane shape.

In the drawings, the X-axis direction and the Y-axis direction may each refer to a direction parallel with a flat surface of the upper surface or the lower surface of the first redistribution structure 100, and the X-axis direction and the Y-axis direction may be substantially perpendicular to each other. The Z-axis direction may refer to a direction that is substantially perpendicular to a surface of the upper surface or the lower surface of the first redistribution structure 100. In other words, the Z-axis direction may be a direction that is substantially perpendicular to the X-Y plane.

In the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The first redistribution pattern 130 may be formed to penetrate the first redistribution insulating layer 110 from the upper surface to the lower surface of the first redistribution structure 100, and the first redistribution insulating layers 110 may be stacked in the vertical direction (Z direction). The first redistribution pattern 130 may provide an electrical connection from the upper surface to the lower surface of the first redistribution structure 100.

The first redistribution pattern 130 may be a metal such as copper (Cu), aluminum (Al), tungsten (W), titanium (Ti), tantalum (Ta), indium (In), molybdenum (Mo), manganese (Mn), Cobalt (Co), tin (Sn), nickel (Ni), magnesium (Mg), rhenium (Re), beryllium (Be), gallium (Ga), ruthenium (Ru), etc. or an alloy of metals. However, the present inventive concept is not limited thereto, and in embodiments of the present inventive concept, the first redistribution pattern 130 may be formed by stacking a metal or an alloy of metals on a seed layer including copper, titanium, titanium nitride, and/or titanium tungsten.

The first redistribution insulating layer 110 may include photo imagable dielectric (PID) or photosensitive polyimide (PSPI).

The first redistribution pattern 130 may include a first redistribution line pattern 133, a first redistribution via pattern 131, and a first upper pad 135. The first redistribution line pattern 133 may have a shape extending in the horizontal direction along at least one surface of the upper surface and the lower surface of each of the plurality of first redistribution insulating layers 110 that are stacked on each other in the vertical direction (Z direction). The first redistribution via pattern 131 may have a shape extending and penetrating the first redistribution insulating layer 110 in the vertical direction (Z direction). The first redistribution via pattern 131 may electrically connect the first redistribution line patterns 133 that are arranged at different levels from each other. In embodiments of the present inventive concept, at least some of the first redistribution line patterns 133 may be formed and integrated with some of the first redistribution via patterns 131. The first upper pad 135 may be arranged on the upper surface of the first redistribution structure 100. The first upper pad 135 may be understood as the uppermost first redistribution line pattern 133 from among the first redistribution line patterns 133.

The external connection terminal 160 may be arranged on the lower surface of the first redistribution structure 100. The external connection terminal 160 may be electrically connected to an external device, for example, a mother board. The external connection terminal 160 may be formed by a solder ball. However, in embodiments of the present inventive concept, the external connection terminal 160 may have a structure including a pillar and solder. The external connection terminal 160 may include at least one of copper (Cu), silver (Ag), gold (Au), and/or tin (Sn).

The first conductive pillar 180 may be arranged spaced apart from the first redistribution structure 100 in the vertical direction and may be disposed on the upper surface of the first redistribution structure 100. The first conductive pillar 180 may be arranged on the upper surface of the first upper pad 135. The first conductive pillar 180 may be formed to penetrate the second molding member 190 in the vertical direction (Z direction). The first conductive pillar 180 may include, for example, copper (Cu). The first conductive pillar 180 may be a vertical connecting conductor for electrically connecting the first redistribution structure 100 and the fourth redistribution structure 600 to each other.

An aspect ratio, i.e., a width D1-to-height D2 of the first conductive pillar 180 may be about 1:2 or greater, as an example. In embodiments of the present inventive concept, the aspect ratio of the first conductive pillar 180 may be in a range from about 1:2 to about 1:5. However, the present inventive concept is not limited thereto, and the aspect ratio of the first conductive pillar 180 may be about 1:5 or greater.

In embodiments of the present inventive concept, there may be a plurality of first conductive pillars 180. The plurality of first conductive pillars 180 may be arranged spaced apart from each other in the horizontal direction. The plurality of first conductive pillars 180 may respectively be arranged on upper surfaces of the first upper pads 135.

The first conductive pillar 180 might not be formed through a plating process. The first conductive pillar 180 may be provided in a pin shape, a cylindrical shape, or rectangular prism shape, and may be arranged on the upper surface of the first redistribution structure 100 through a pick-and-place process.

A first film 185 may cover a surface of the first conductive pillar 180. In embodiments of the present inventive concept, the first film 185 may cover a lower surface and a lateral surface of the first conductive pillar 180. In embodiments of the present inventive concept, the first film 185 may include tin (Sn). For example, the first film 185 may cover the surface of the first conductive pillar 180 through a plating process. In embodiments of the present inventive concept, the first film 185 may be formed through barrel plating. The first film 185 may be formed through the plating process before the first conductive pillar 180 is arranged on the upper surface of the first redistribution structure 100. In embodiments of the present inventive concept, a thickness T1 of the first film 185 may be in a range from about 1 μm to about 3 μm. In embodiments of the present inventive concept, a melting point of the first film 185 may be lower than a melting point of the first conductive pillar 180.

The second redistribution structure 200 may be arranged on the upper surface of the first redistribution structure 100. A first bump 260 may be arranged between the first redistribution structure 100 and the second redistribution structure 200. The first bump 260 may electrically connect the first redistribution structure 100 to the second redistribution structure 200. The first bump 260 may be arranged on the first upper pad 135 of the first redistribution structure 100. In embodiments of the present inventive concept, the first bump 260 may include a solder ball. In embodiments of the present inventive concept, the first bump 260 may have a structure including a pillar and solder. The first bump 260 may include at least one of copper (Cu), silver (Ag), gold (Au), and/or tin (Sn).

The second redistribution structure 200 may include a second redistribution pattern 230 and a second redistribution insulating layer 210 covering the second redistribution pattern 230. The second redistribution pattern 230 may include a second redistribution line pattern 233 and a second redistribution via pattern 231. The second redistribution pattern 230 and the second redistribution insulating layer 210 may be identical or similar to the first redistribution pattern 130 and the first redistribution insulating layer 110, respectively, and thus, detailed description thereon is omitted. A footprint of the second redistribution structure 200 may be less than a footprint of the first redistribution structure 100. For example, a size of the second redistribution structure 200 may be less than a size of the first redistribution structure 100. The second redistribution structure 200 may be electrically connected to each of a second conductive pillar 380, the first chip 300, and the first bump 260.

The first chip 300 may be arranged on an upper surface of the second redistribution structure 200. In embodiments of the present inventive concept, the first chip 300 may include a logic chip. The first chip 300 may include, for example, a physical layer (PHY) and a modem. However, the present inventive concept is not limited thereto, and the first chip 300 may be a microprocessor such as a central processing unit (CPU), a graphic processing unit (GPU), or an application processor (AP), an analog device, or a digital signal processor. In embodiments of the present inventive concept, the first chip 300 may include a memory chip. The memory chip may be, for example, a volatile memory chip such as dynamic random access memory (DRAM) or static random access memory or a non-volatile memory chip such as phase-change random access memory (PRAM), magneto-resistive random access memory (MRAM), ferroelectric random access memory (FeRAM), or resistive random access memory (PRAM).

The first chip 300 may be mounted onto the second redistribution structure 200 by a flip chip method through a second bump 350 such as a microbump. In embodiments of the present inventive concept, an under-fill material layer 340 covering the second bump 350 may be arranged between the first chip 300 and the second redistribution structure 200. The under-fill material layer 340 may include, for example, epoxy resin formed by a capillary under-fill method. However, in embodiments of the present inventive concept, the first molding member 390 may be filled in a gap between the first chip 300 and the second redistribution structure 200 through a molded under-fill process. In this case, the under-fill material layer 340 may be omitted.

The first chip 300 may include a first semiconductor substrate 330, a first through via 335, and an element layer 310. The first semiconductor substrate 330 may include silicon (Si), for example, crystalline silicon, polycrystalline silicon, or amorphous silicon. The first semiconductor substrate 330 may include a semiconductor element, such as germanium (Ge), or a compound semiconductor, such as silicon carbide (SiC), gallium arsenide (GaAs), indium arsenide (InAs), and indium phosphide (InP). The element layer 310 may include a plurality of semiconductor elements and interlayer insulating films covering the plurality of semiconductor elements. The semiconductor elements may include, for example, switching elements, such as a transistor, etc. The first chip 300 may be mounted on the upper surface of the second redistribution structure 200 such that the element layer 310 is disposed on the second redistribution structure 200. The first through via 335 may be formed to penetrate the first semiconductor substrate 330 in the vertical direction (Z direction). In embodiments of the present inventive concept, the first through via 335 may penetrate the first semiconductor substrate 330 in the vertical direction (Z direction) from the upper surface to the lower surface of the first semiconductor substrate 330 and may further penetrate a part of the element layer 310 in the vertical direction (Z direction). For example, the first through via 335 may have a tapered shape in which a horizontal width decreases or increases. For example, the tapered shape may have a horizontal width that decreases or increases as a level in the vertical direction increases away from an upper surface of the second redistribution structure 200. At least a part of the first through via 335 may have a pillar shape, a cylindrical shape, or a rectangular prism shape. The first through via 335 may be a through silicon via (TSV).

The first through via 335 may be electrically connected to a second through via 395. For example, an upper surface of the first through via 335 may be in contact with a lower surface of the second through via 395. The second through via 395 may be formed to penetrate the first molding member 390 in the vertical direction (Z direction). The second through via 395 may be a through mold via (TMV). For example, the second through via 395 may have a tapered shape.

The second conductive pillar 380 may be arranged spaced apart from the first chip 300 in the horizontal direction on the upper surface of the second redistribution structure 200. The second conductive pillar 380 may be formed to penetrate the first molding member 390 in the vertical direction (Z direction). The second conductive pillar 380 may include, for example, copper (Cu). The second conductive pillar 380 may be a vertical connecting conductor for electrically connecting the second redistribution structure 200 and the third redistribution structure 400 to each other.

The first molding member 390 may cover the first chip 300, the second through via 395, and the second conductive pillar 380. The first molding member 390 may include thermosetting resin such as epoxy resin, thermoplastic resin such as polyimide, or resin including a stiffener such as an inorganic filler, for example, Ajinomoto Build-up Film (ABF), FR-4, BT, etc.; however, the present inventive concept is not limited thereto, and the first molding member 390 may include a molding material such as EMC or a photosensitive material such as photoimagable encapsulant (PIE). In embodiments of the present inventive concept, a part of the first molding member 390 may include an insulating material such as a silicon oxide film, a silicon nitride film, or a silicon oxynitride film.

The third redistribution structure 400 may be arranged on the upper surface of the first molding member 390. The third redistribution structure 400 may include a third redistribution pattern 430 and a third redistribution insulating layer 410 covering the third redistribution pattern 430. The third redistribution pattern 430 may include a third redistribution line pattern 433 and a third redistribution via pattern 431 that are connected to each other. The third redistribution pattern 430 may be electrically connected to the second through via 395.

The second chip 500 may be arranged on an upper surface of the third redistribution structure 400. The second chip 500 may be a logic chip. The logic chip may include, for example, a CPU, a GPU, or an AP. However, the present inventive concept is not limited thereto, and the second chip 500 may include a memory chip. In embodiments of the present inventive concept, the second chip 500 may be arranged on the upper surface of the third redistribution structure 400 through a flip chip method.

A third molding member 590 may be formed to cover the second chip 500 on the upper surface of the third redistribution structure 400. The third molding member 590 may include thermosetting resin such as epoxy resin, thermoplastic resin such as polyimide, or resin including a stiffener such as an inorganic filler, for example, ABF, FR-4, BT, etc.; however, the present inventive concept is not limited thereto, and the third molding member 590 may include a molding material such as EMC or a photosensitive material such as PIE. In embodiments of the present inventive concept, a part of the third molding member 590 may include an insulating material such as a silicon oxide film, a silicon nitride film, or a silicon oxynitride film.

The second molding member 190 may cover the first conductive pillar 180, the second redistribution structure 200, the first molding member 390, the third redistribution structure 400, and the third molding member 590 on the upper surface of the first redistribution structure 100. The second molding member 190 may include thermosetting resin such as epoxy resin, thermoplastic resin such as polyimide, or resin including a stiffener such as an inorganic filler, for example, ABF, FR-4, BT, etc.; however, the present inventive concept is not limited thereto, and the second molding member 190 may include a molding material such as EMC or a photosensitive material such as PIE.

The second molding member 190 may cover the first film 185. For example, the first film 185 may be in contact with the second molding member 190 in the horizontal direction. No empty space may be formed between the second molding member 190 and the first film 185.

The fourth redistribution structure 600 may be arranged on the upper surface of the second molding member 190, the upper surface of the third molding member 590, and the upper surface of the second chip 500. The fourth redistribution structure 600 may include a fourth redistribution pattern 630 and a fourth redistribution insulating layer 610 covering the fourth redistribution pattern 630. The fourth redistribution pattern 630 may include a fourth redistribution line pattern 633 and a fourth redistribution via pattern 631. The fourth redistribution line pattern 633 and the fourth redistribution via pattern 631 may be identical or similar to the first redistribution line pattern 133 and the first redistribution via pattern 131, respectively, and thus, detailed description thereon is omitted.

The semiconductor package 10 according to embodiments of the present inventive concept may include the first conductive pillar 180 having an aspect ratio of 1:2 or more, and the first conductive pillar 180 might not be formed by a plating process. The first conductive pillar 180 may be formed by arranging a conductive pin having a pin shape and manufactured separately onto the upper surface of the first redistribution structure 100 through a pick-and-place process.

In this regard, the first film 185 may be arranged on the lower surface and the lateral surface of the first conductive pillar 180, and after arranging the first conductive pillar 180 plated with the first film 185 on the upper surface of the first redistribution structure 100, the first film 185 may be melted by applying heat that is higher than a melting point of the first film 185 and then coagulated. Through the coagulation of the first film 185, the first conductive pillar 180 may be fixed onto the upper surface of the first redistribution structure 100.

In related arts, formation of the first conductive pillar 180 generally uses a photoresist and a plating process. Moreover, when the first conductive pillar 180 having a high aspect ratio is required, the application of photoresist and the plating process may be performed more than twice. However, according to embodiments of the present inventive concept, as the application of photoresist and the plating process are omitted, and thus the process is simplified, the limit in the aspect ratio of the first conductive pillar 180 and the issue of ununified heights of the first conductive pillars 180 may be prevented. In addition, the issue of residual foreign substances during the application of photoresist may also be prevented.

Moreover, as solder balls are not required to fix the first conductive pillar 180 onto the first upper pad 135, the first conductive pillar 180 having a pitch less than a limit pitch of solder balls, which is a horizontal thickness, may be formed.

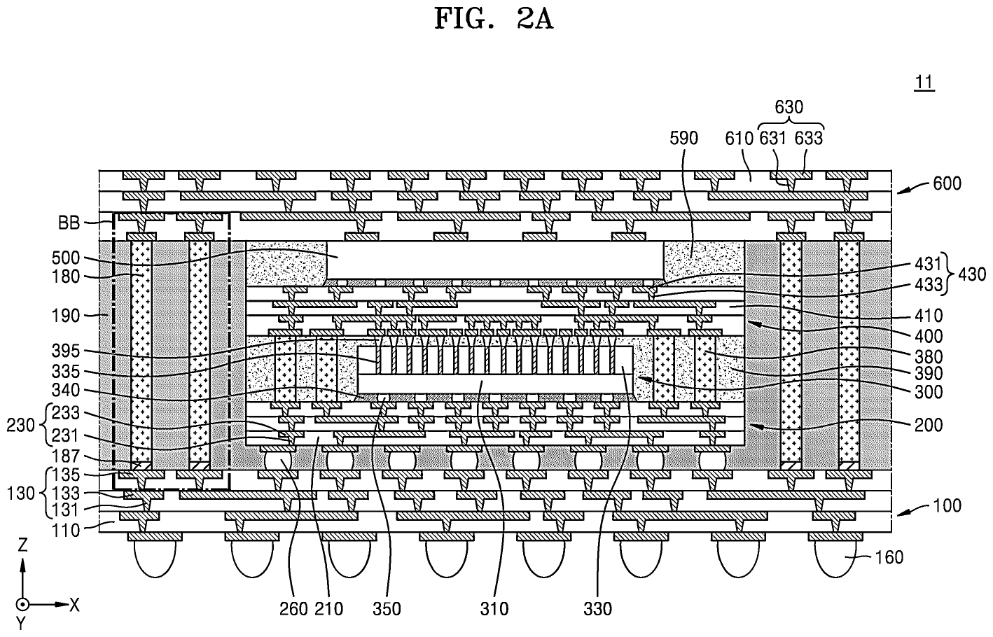

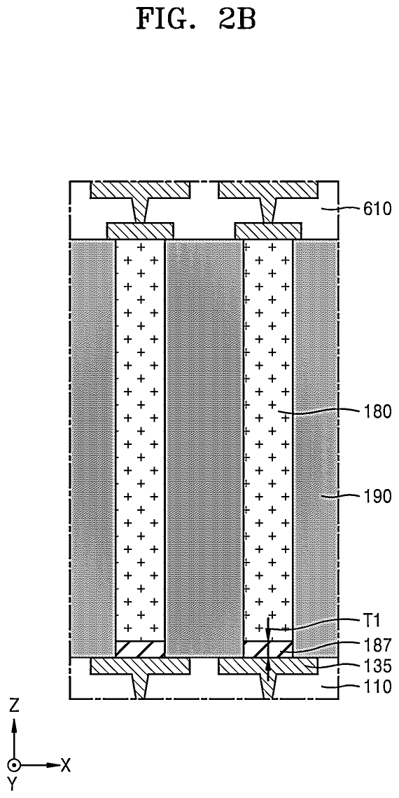

FIG. 2A is a cross-sectional view along an X-Z plane, schematically illustrating a semiconductor package according to embodiments of the present inventive concept. FIG. 2B is an enlarged view illustrating part BB of FIG. 2A. Hereinafter, any redundant explanation described in relation to the semiconductor package 10 of FIGS. 1A and 1B and a semiconductor package 11 of FIGS. 2A and 2B is omitted or briefly discussed, and embodiments of the present inventive concept are described with focus on the differences.

Referring to FIGS. 2A and 2B, the semiconductor package 11 may include the first redistribution structure 100, the second redistribution structure 200, the first conductive pillar 180, the first chip 300, the third redistribution structure 400, the second chip 500, the first molding member 390, the second molding member 190, and the fourth redistribution structure 600.

The first redistribution structure 100 may be electrically connected to each of the first conductive pillar 180, the second redistribution structure 200, and the external connection terminal 160, and may include the first redistribution pattern 130 and the first redistribution insulating layer 110 that covers the first redistribution pattern 130. The first redistribution pattern 130 may include the first redistribution line pattern 133 and the first redistribution via pattern 131. The external connection terminal 160 may be arranged on the lower surface of the first redistribution structure 100.

The first conductive pillar 180 may be arranged spaced apart from the first redistribution structure 100 in the vertical direction. A first film 187 may be arranged on the lower surface of the first conductive pillar 180. For example, the first film 187 may be disposed between the lower surface of the first conductive pillar 180 and the first redistribution structure 100. The first film 187 may be arranged between the first conductive pillar 180 and the first upper pad 135. The first film 187 might not cover the lateral surface and the upper surface of the first conductive pillar 180. The first film 187 may fix the first conductive pillar 180 onto the upper surface of the first upper pad 135. In embodiments of the present inventive concept, the first film 187 may include tin. In embodiments of the present inventive concept, the first film 187 may be formed on the upper surface of the first upper pad 135 through a plating process. In embodiments of the present inventive concept, a thickness T1 of the first film 187 may be in a range from about 1 μm to about 3 μm. A melting point of the first film 187 may be lower than a melting point of the first conductive pillar 180.

The second redistribution structure 200 may be arranged on the upper surface of the first redistribution structure 100. The first bump 260 may be arranged between the first redistribution structure 100 and the second redistribution structure 200. The first bump 260 may electrically connect the first redistribution structure 100 to the second redistribution structure 200. The first bump 260 may be arranged on the first upper pad 135 of the first redistribution structure 100. The second redistribution structure 200 may include the second redistribution pattern 230 and the second redistribution insulating layer 210 that covers the second redistribution pattern 230. The second redistribution pattern 230 may include the second redistribution line pattern 233 and the second redistribution via pattern 231.

The first chip 300 may be arranged on the upper surface of the second redistribution structure 200. The first chip 300 may be mounted onto the second redistribution structure 200 by the flip chip method through the second bump 350 such as a microbump. The first chip 300 may include the first semiconductor substrate 330, the first through via 335, and the element layer 310.

The second conductive pillar 380 may be arranged spaced apart from the first chip 300 in the horizontal direction on the upper surface of the second redistribution structure 200. The second conductive pillar 380 may be formed to penetrate the first molding member 390 in the vertical direction (Z direction). The first molding member 390 may cover the first chip 300, the second through via 395, and the second conductive pillar 380. The third redistribution structure 400 may be arranged on the upper surface of the first molding member 390. The third redistribution structure 400 may include the third redistribution pattern 430 and the third redistribution insulating layer 410 that covers the third redistribution pattern 430. The third redistribution pattern 430 may include the third redistribution line pattern 433 and the third redistribution via pattern 431 that are connected to each other. The second chip 500 may be arranged on the upper surface of the third redistribution structure 400. The third molding member 590 may be formed to cover the second chip 500 on the upper surface of the third redistribution structure 400. The second molding member 190 may cover the first conductive pillar 180, the second redistribution structure 200, the first molding member 390, the third redistribution structure 400, and the third molding member 590 on the upper surface of the first redistribution structure 100. The fourth redistribution structure 600 may be arranged on the upper surfaces of the second molding member 190, the third molding member 590, and the second chip 500. The fourth redistribution structure 600 may include the fourth redistribution pattern 630 and the fourth redistribution insulating layer 610 that covers the fourth redistribution pattern 630. The fourth redistribution pattern 630 may include the fourth redistribution line pattern 633 and the fourth redistribution via pattern 631.

In the semiconductor package 11 according to an embodiment of the present inventive concept, after plating the upper surface of the first upper pad 135 with the first film 187, a copper pin having a pin shape may be arranged on the upper surface of the first upper pad 135, and by applying heat thereto, the first conductive pillar 180 may be arranged on the upper surface of the first upper pad 135. In the semiconductor package 11 according to embodiments of the present inventive concept, as the first film 187 is arranged only on the lower surface of the first conductive pillar 180, the process expense may be reduced.

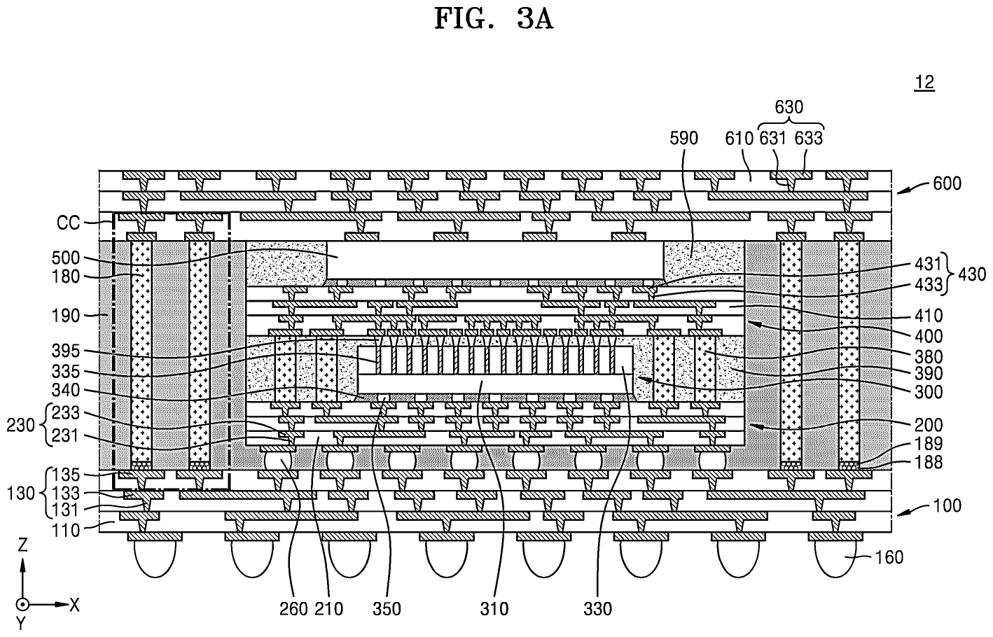

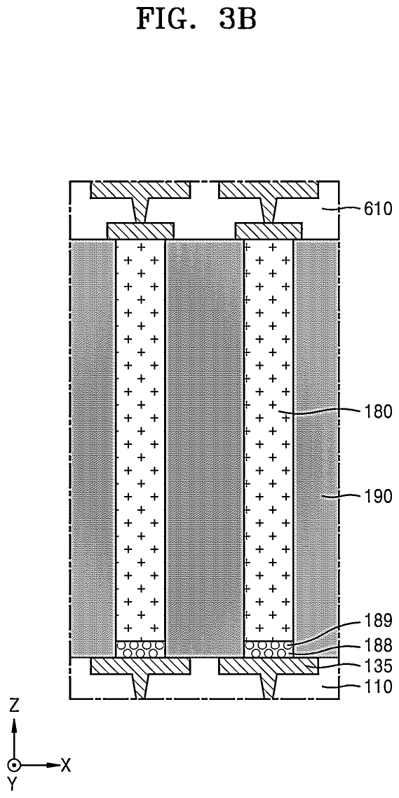

FIG. 3A is a cross-sectional view along an X-Z plane, schematically illustrating a semiconductor package according to embodiments of the present inventive concept. FIG. 3B is an enlarged view illustrating part CC of FIG. 3A. Hereinafter, any redundant explanation described in relation to the semiconductor package 10 of FIGS. 1A and 1B and a semiconductor package 12 of FIGS. 3A and 3B is omitted or briefly discussed, and the embodiments are described with focus on the differences.

Referring to FIGS. 3A and 3B, the semiconductor package 12 may include the first redistribution structure 100, the second redistribution structure 200, the first conductive pillar 180, the first chip 300, the third redistribution structure 400, the second chip 500, the first molding member 390, the second molding member 190, and the fourth redistribution structure 600.

The first redistribution structure 100 may be electrically connected to each of the first conductive pillar 180, the second redistribution structure 200, and an external connection terminal 160, and may include a first redistribution pattern 130 and a first redistribution insulating layer 110 that covers the first redistribution pattern 130. The first redistribution pattern 130 may include the first redistribution line pattern 133 and the first redistribution via pattern 131. The external connection terminal 160 may be arranged on the lower surface of the first redistribution structure 100.

The first conductive pillar 180 may be arranged spaced apart from the first redistribution structure 100 in the vertical direction and may be disposed on the upper surface of the first redistribution structure 100. The first film 187 might not be arranged on the lower surface of the first conductive pillar 180.

A solder ball 189 and a junction layer 188 may be arranged between the first conductive pillar 180 and the first upper pad 135. A plurality of solder balls 189 may be arranged between the first conductive pillar 180 and the first upper pad 135. In embodiments of the present inventive concept, the junction layer 188 may be a layer formed when the plurality of solder balls 189 are melted. For example, the plurality of solder balls 189 may be disposed in the junction layer 188. The solder ball 189 may include a conductive material, for example, at least one of tin (Sn), silver (Ag), copper (Cu), and aluminum (Al). The first conductive pillar 180 may be fixed onto the upper surface of the first upper pad 135 through the solder ball 189.

The second redistribution structure 200 may be arranged on the upper surface of the first redistribution structure 100. The first bump 260 may be arranged between the first redistribution structure 100 and the second redistribution structure 200. The first bump 260 may electrically connect the first redistribution structure 100 to the second redistribution structure 200. The first bump 260 may be arranged on the first upper pad 135 of the first redistribution structure 100. The second redistribution structure 200 may include the second redistribution pattern 230 and the second redistribution insulating layer 210 that covers the second redistribution pattern 230. The second redistribution pattern 230 may include the second redistribution line pattern 233 and the second redistribution via pattern 231 that are connected to each other.

The first chip 300 may be arranged on the upper surface of the second redistribution structure 200. The first chip 300 may be mounted onto the second redistribution structure 200 by a flip chip method through a second bump 350 such as a microbump. The first chip 300 may include the first semiconductor substrate 330, the first through via 335, and the element layer 310.

The second conductive pillar 380 may be arranged spaced apart from the first chip 300 in the horizontal direction on the upper surface of the second redistribution structure 200. The second conductive pillar 380 may be formed to penetrate the first molding member 390 in the vertical direction (Z direction). The first molding member 390 may cover the first chip 300, the second through via 395, and the second conductive pillar 380. The third redistribution structure 400 may be arranged on the upper surface of the first molding member 390. The third redistribution structure 400 may include the third redistribution pattern 430 and the third redistribution insulating layer 410 that covers the third redistribution pattern 430. The third redistribution pattern 430 may include the third redistribution line pattern 433 and the third redistribution via pattern 431. The second chip 500 may be arranged on the upper surface of the third redistribution structure 400. The third molding member 590 may be formed to cover the second chip 500 on the upper surface of the third redistribution structure 400. The second molding member 190 may cover the first conductive pillar 180, the second redistribution structure 200, the first molding member 390, the third redistribution structure 400, and the third molding member 590 on the upper surface of the first redistribution structure 100. The fourth redistribution structure 600 may be arranged on the upper surfaces of the second molding member 190, the third molding member 590, and the second chip 500. The fourth redistribution structure 600 may include the fourth redistribution pattern 630 and the fourth redistribution insulating layer 610 that covers the fourth redistribution pattern 630. The fourth redistribution pattern 630 may include the fourth redistribution line pattern 633 and the fourth redistribution via pattern 631 that are connected to each other.

In the semiconductor package 12 according to embodiments of the present inventive concept, the plurality of solder balls 189 may be arranged between the first conductive pillar 180 and first upper pad 135. For example, the plurality of solder balls 189 may be arranged between a copper pin having a pin shape and the first upper pad 135. By applying heat to the plurality of solder balls 189, the first conductive pillar 180 may be arranged on the upper surface of the first upper pad 135. In the semiconductor package 12 according to embodiments of the present inventive concept, through the solder balls 189, the first conductive pillar 180 having a high aspect ratio may be arranged on the upper surface of the first upper pad 135.

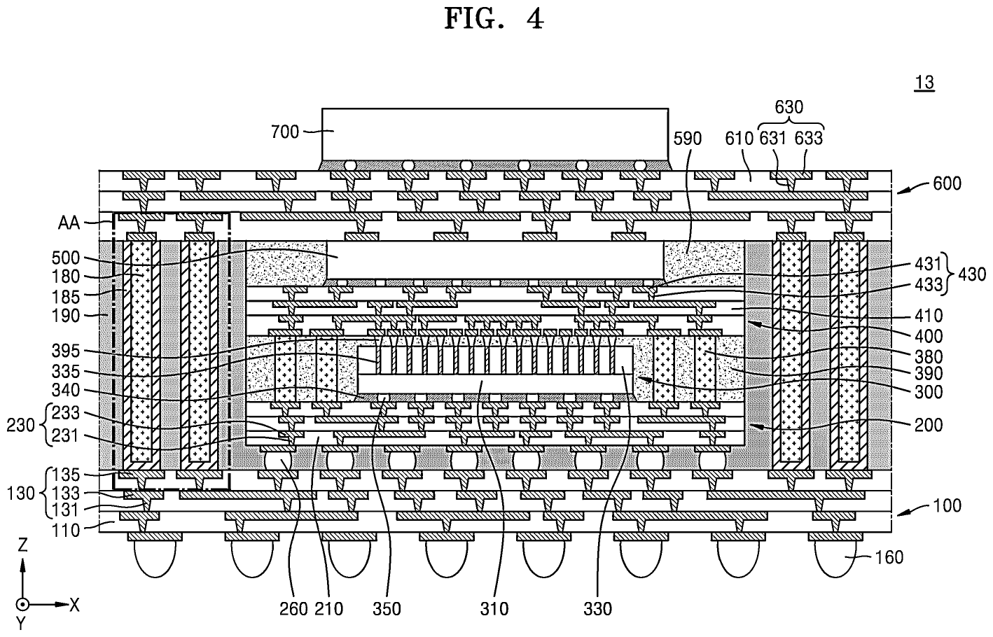

FIG. 4 is a cross-sectional view along an X-Z plane, schematically illustrating a semiconductor package according to embodiments of the present inventive concept. Hereinafter, any redundant explanation described in relation to the semiconductor package 10 of FIGS. 1A and 1B and the semiconductor package 13 of FIG. 4 is omitted or briefly discussed, and the embodiments of the present inventive concept are described with focus on the differences.

Referring to FIG. 4, a semiconductor package 13 may include the first redistribution structure 100, the second redistribution structure 200, the first conductive pillar 180, the first chip 300, the third redistribution structure 400, the second chip 500, the first molding member 390, the second molding member 190, the fourth redistribution structure 600, and a third chip 700.

The third chip 700 may be arranged on the upper surface of the fourth redistribution structure 600. In embodiments of the present inventive concept, the third chip 700 may include at least one of a memory chip and a logic chip. In embodiments of the present inventive concept, the third chip 700 may be arranged on the upper surface of the fourth redistribution structure 600 through a flip chip method. The third chip 700 may be electrically connected to the fourth redistribution structure 600. The third chip 700 may be electrically connected to the fourth redistribution pattern 630. Although FIG. 4 illustrates that one third chip 700 is arranged on the upper surface of the fourth redistribution structure 600, the present inventive concept is not limited thereto, and a plurality of third chips 700 may be arranged on the upper surface of the fourth redistribution structure 600.

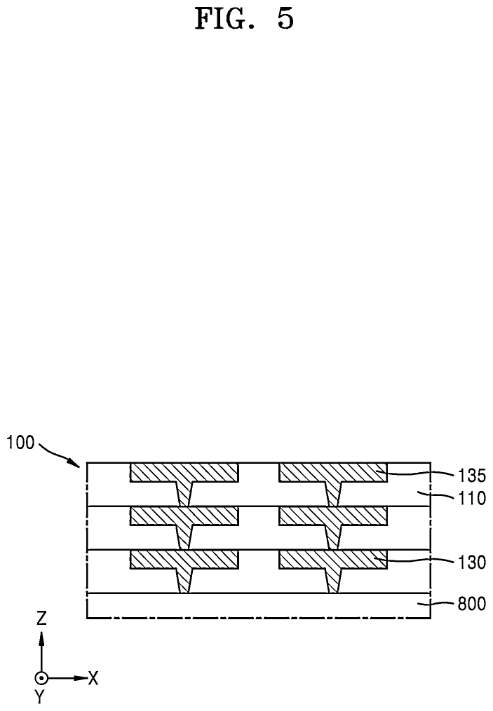

FIGS. 5 to 8C are schematic diagrams illustrating a method of manufacturing a semiconductor package according to embodiments of the present inventive concept. Hereinafter, any redundant explanation described with reference to FIGS. 1A to 3B is omitted or briefly discussed, and the embodiments of the present inventive concept are described with focus on the differences. In addition, FIGS. 5 to 8C illustrate only the first redistribution structure 100, the first film 185 and 187, the solder balls 189, and the first conductive pillar 180 from among the components illustrated in FIGS. 1A to 3B for convenience.

Referring to FIG. 5, the first redistribution structure 100 may be attached onto a carrier substrate 800. The first redistribution structure 100 may include a plurality of first redistribution insulating layers 110 and the first redistribution pattern 130. The first upper pad 135 may be provided at the upper surface of the uppermost first redistribution insulating layer 110.

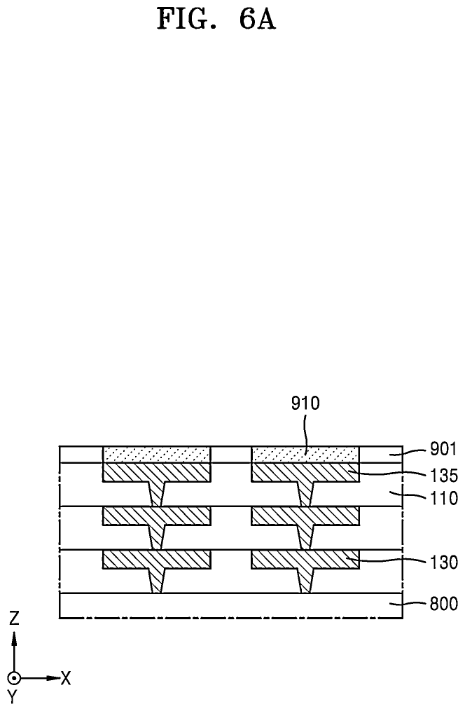

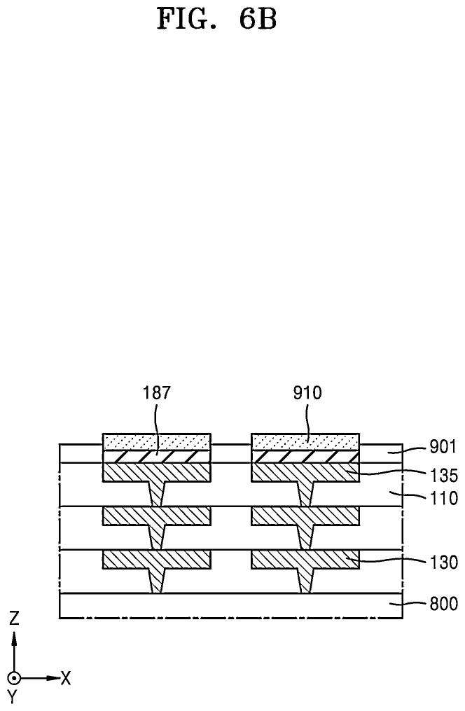

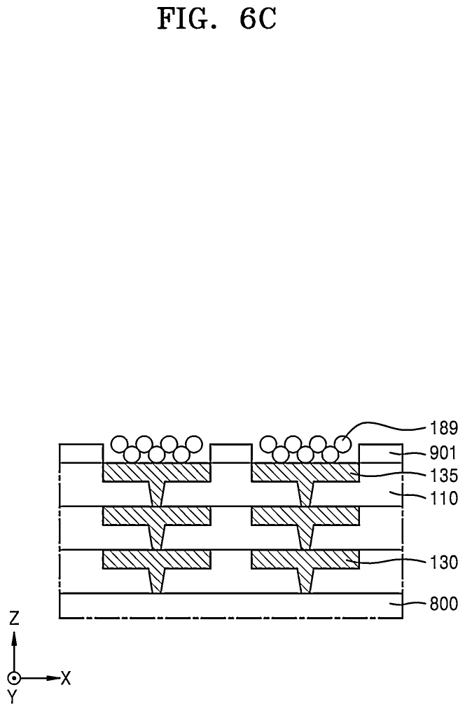

FIGS. 6A to 6C are schematic diagrams illustrating the semiconductor package 10 of FIGS. 1A and 1B, the semiconductor package 11 of FIGS. 2A and 2B, and the semiconductor package 12 of FIGS. 3A and 3B, respectively.

First, referring to FIG. 6A, a first mask 901 may be arranged on the upper surface of the uppermost first redistribution insulating layer 110. The first mask 901 may be arranged in such a manner that an opening of the first mask 901 overlaps the first upper pad 135 in the vertical direction (Z direction). A second film 910 may be applied onto the opening of the first mask 901. The second film 910 may include, for example, flux.

Referring to FIG. 6B, the first mask 901 may be arranged on the upper surface of the uppermost first redistribution insulating layer 110. The first mask 901 may be arranged in such a manner that the opening of the first mask 901 overlaps the first upper pad 135 in the vertical direction (Z direction). The upper surface of the first upper pad 135 may be exposed upwards in the vertical direction (Z direction) by the first mask 901. The first film 187 may be arranged on the exposed upper surface of the first upper pad 135. The first film 187 may be formed by a plating process. After forming the first film 187, the second film 910 may be applied onto the upper surface of the first film 187.

Referring to FIG. 6C, the first mask 901 may be arranged on the upper surface of the first redistribution insulating layer 110. The first mask 901 may be arranged in such a manner that the opening of the first mask 901 overlaps the first upper pad 135 in the vertical direction (Z direction). The upper surface of the first upper pad 135 may be exposed upwards in the vertical direction (Z direction) by the first mask 901. The plurality of solder balls 189 may be arranged on the exposed upper surface of the first upper pad 135. The plurality of solder balls 189 may be arranged on the upper surface of each of the plurality of first upper pads 135.

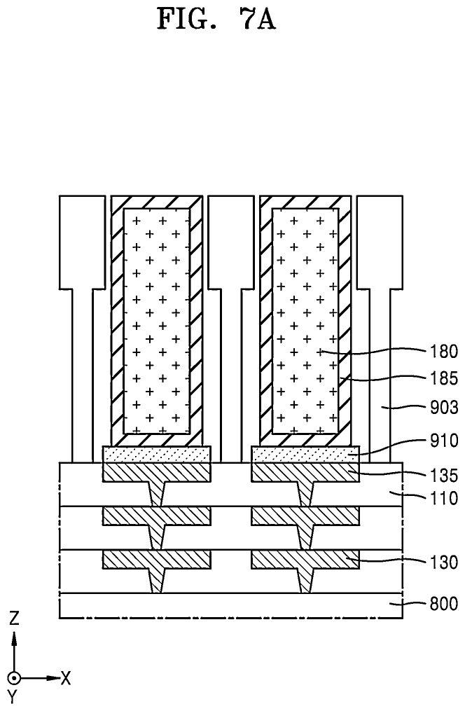

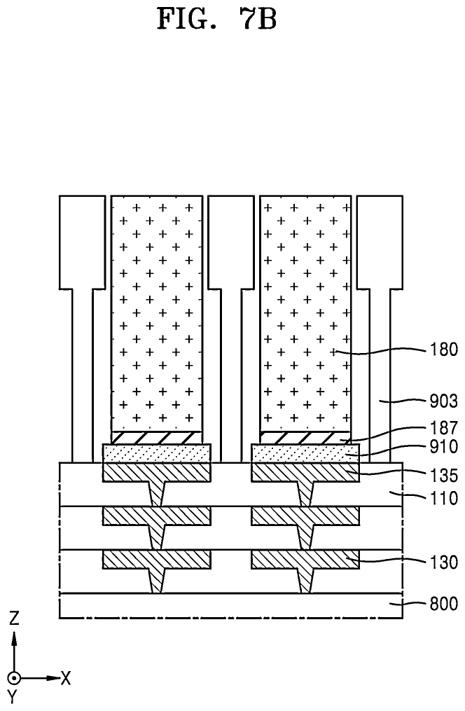

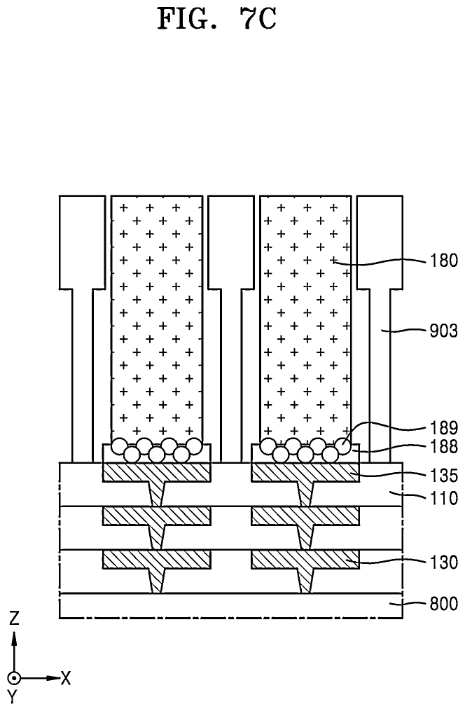

FIGS. 7A to 7C are schematic diagrams illustrating the semiconductor package 10 of FIGS. 1A and 1B, the semiconductor package 11 of FIGS. 2A and 2B, and the semiconductor package 12 of FIGS. 3A and 3B, respectively.

Referring to FIG. 7A, the first mask 901 in FIG. 6A may be removed, and a second mask 903 may be arranged on the uppermost first redistribution insulating layer 110. The second mask 903 may be arranged in such a manner that an opening of the second mask 903 overlaps the second film 910 in the vertical direction (Z direction).

In embodiments of the present inventive concept, the thickness of the second mask 903 in the first horizontal direction (X direction) may vary according to a vertical level. For example, the thickness of a lower portion of the second mask 903 in the first horizontal direction (X direction) may be less than the thickness of an upper portion of the second mask 903 in the first horizontal direction (X direction).

After the second mask 903 is arranged, an entire surface of the first conductive pillar 180 may be plated with the first film 185 and may be arranged in the opening of the second mask 903. The first conductive pillar 180 may be manufactured elsewhere in a pin shape and may be provided. The first film 185 may cover the lower surface, the lateral surface, and the upper surface of the first conductive pillar 180. For example, the first film 185 may cover all of the lower surface, the lateral surface, and the upper surface of the first conductive pillar 180. The first conductive pillar 180, which is plated with the first film 185, may be arranged on the upper surface of the second film 910.

Referring to FIG. 7B, the first mask 901 in FIG. 6B may be removed, and the second mask 903 may be arranged on the uppermost first redistribution insulating layer 110. The second mask 903 may be arranged in such a manner that the opening of the second mask 903 overlaps the first upper pad 135 in the vertical direction (Z direction). Then, the first conductive pillar 180 may be arranged on the upper surface of the first upper pad 135. The upper surface of the first upper pad 135 may be plated with the first film 187, and the lower surface of the first conductive pillar 180 may be in contact with the upper surface of the first film 187.

Referring to FIG. 7C, the first mask 901 in FIG. 6C may be removed, and the second mask 903 may be arranged on the uppermost first redistribution insulating layer 110. The second mask 903 may be arranged in such a manner that the opening of the second mask 903 overlaps the solder balls 189 in the vertical direction (Z direction). Then, the first conductive pillar 180 may be arranged on the upper surface of the solder balls 189. The lower surface of the first conductive pillar 180 may be in contact with the upper surface of the solder balls 189.

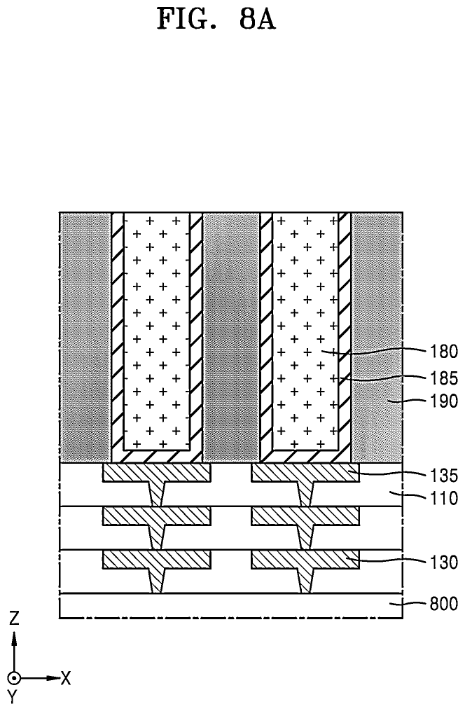

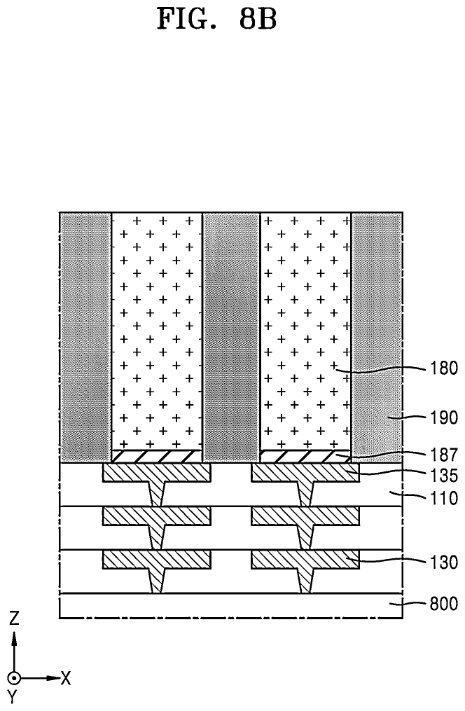

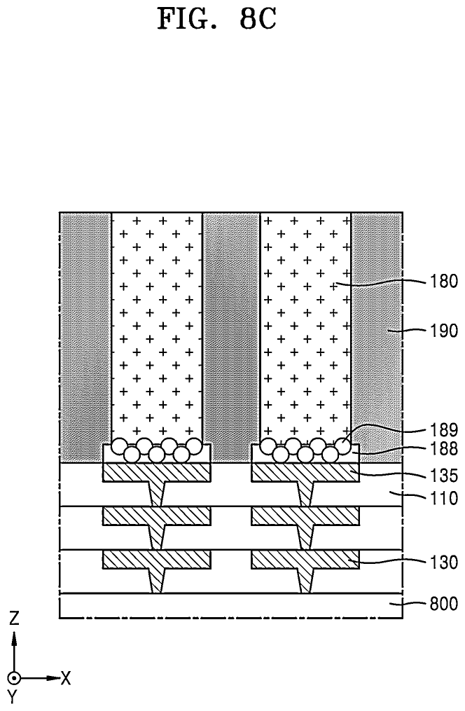

FIGS. 8A to 8C are schematic diagrams illustrating the semiconductor package 10 of FIGS. 1A and 1B, the semiconductor package 11 of FIGS. 2A and 2B, and the semiconductor package 12 of FIGS. 3A and 3B, respectively.

Referring to FIG. 8A, the second mask 903 in FIG. 7A may be removed, and the first film 185 may be melted by applying heat and then coagulated such that the first conductive pillar 180 is fixed onto the upper surface of the first upper pad 135. Then, after forming the second molding member 190 covering the first conductive pillar 180, the upper surface thereof may be ground. For example, the grinding may be performed through a CMP process, etc. As the first film 185, which is arranged on the upper surface of the first conductive pillar 180, is removed by the grinding, the upper surface of the first conductive pillar 180 may be exposed upwards in the vertical direction (Z direction).

Referring to FIG. 8B, the second mask 903 in FIG. 7B may be removed, and the first film 187 may be melted by applying heat and then coagulated such that the first conductive pillar 180 is fixed onto the upper surface of the first upper pad 135. Then, after forming the second molding member 190 covering the first conductive pillar 180 and the first film 185, the upper surface thereof may be ground such that the upper surface of the first conductive pillar 180 is arranged at substantially the same level as the upper surface of the second molding member 190.

Referring to FIG. 8C, the second mask 903 in FIG. 7C may be removed, and the solder balls 189 may be melted by applying heat and then coagulated such that the first conductive pillar 180 is fixed onto the upper surface of the first upper pad 135. The junction layer 188 may be formed from the melted solder balls 189. Then, after forming the second molding member 190 covering the first conductive pillar 180, the upper surface thereof may be ground such that the upper surface of the first conductive pillar 180 is arranged at substantially the same level as the upper surface of the second molding member 190.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package comprising:
a first redistribution structure;
a second redistribution structure arranged on the first redistribution structure;
a first conductive pillar spaced apart from the second redistribution structure and arranged on the first redistribution structure;
a first chip arranged on the second redistribution structure;
a first molding member covering the first chip and disposed on the second redistribution structure;
a third redistribution structure arranged on the first molding member;
a second chip arranged on the third redistribution structure;
a second molding member covering the first conductive pillar and the first molding member; and
a fourth redistribution structure arranged on the second molding member, wherein a first film is arranged on a first surface of the first conductive pillar, and the first film includes tin (Sn).

2. The semiconductor package of claim 1, wherein the first film covers a second surface of the first conductive pillar.

3. The semiconductor package of claim 2, wherein a thickness of the first film is in a range from about 1 μm to about 3 μm.

4. The semiconductor package of claim 2, wherein a third surface of the first conductive pillar is covered by the fourth redistribution structure.

5. The semiconductor package of claim 1, wherein an aspect ratio of the first conductive pillar is in a range from 1:2 to 1:5.

6. The semiconductor package of claim 1, wherein a size of the first chip is less than a size of the second chip.

7. The semiconductor package of claim 6, further comprising a second conductive pillar arranged spaced apart from the first chip and disposed on the second redistribution structure.

8. The semiconductor package of claim 1, wherein a third chip is arranged on the fourth redistribution structure.

9. The semiconductor package of claim 1, further comprising a second through via penetrating from an upper surface of the first molding member to an upper surface of the first chip in a vertical direction.

10. The semiconductor package of claim 1, wherein a size of the first redistribution structure is greater than a size of the second redistribution structure.

11. The semiconductor package of claim 1, wherein a melting point of the first film is lower than a melting point of the first conductive pillar.

12. A semiconductor package comprising:
a first redistribution structure including an upper surface, a lower surface opposite to the upper surface, and a first upper pad disposed at the upper surface;
a second redistribution structure arranged on the first redistribution structure;
a first conductive pillar spaced apart from the second redistribution structure and on the first upper pad of the first redistribution structure;
a plurality of solder balls arranged between the first upper pad and the first conductive pillar;
a first chip arranged on the second redistribution structure;
a first molding member covering the first chip and disposed on the second redistribution structure;
a third redistribution structure arranged on the first molding member;
a second chip arranged on the third redistribution structure;
a second molding member covering the first conductive pillar and the first molding member; and
a fourth redistribution structure arranged on the second molding member.

13. The semiconductor package of claim 12, wherein a junction layer covering the plurality of solder balls is arranged between the first upper pad and the first conductive pillar.

14. The semiconductor package of claim 12, wherein an aspect ratio of the first conductive pillar is in a range from 1:2 to 1:5.

15. The semiconductor package of claim 12, wherein a length of the first chip in a first horizontal direction is smaller than a length of the second chip in a first horizontal direction.

16. The semiconductor package of claim 15, further comprising a second conductive pillar arranged spaced apart from the first chip on an upper surface of the second redistribution structure.

17. The semiconductor package of claim 12, wherein a third chip is arranged on the fourth redistribution structure.

18. A semiconductor package comprising:
a first redistribution structure including an upper surface, a lower surface opposite to the upper surface, and a first upper pad disposed in the first redistribution structure;
a second redistribution structure arranged on the first redistribution structure;
a first bump arranged between the first redistribution structure and the second redistribution structure;
a first conductive pillar spaced apart from the second redistribution structure and on the first upper pad of the first redistribution structure;
a first film covering a lower surface and a lateral surface of the first conductive pillar;
a first chip arranged on the second redistribution structure;
a second conductive pillar arranged spaced apart from the first chip and disposed on the second redistribution structure;
a first molding member covering the first chip and the second conductive pillar and disposed on the second redistribution structure;
a third redistribution structure arranged on the first molding member;
a second chip arranged on the third redistribution structure and having a size greater than a size of the first chip;
a second molding member covering the first conductive pillar and the first molding member; and
a fourth redistribution structure arranged on the second molding member, wherein a thickness of the first film is in a range from about 1 μm to about 3 μm, a melting point of the first film is lower than a melting point of the first conductive pillar, and
an aspect ratio of the first conductive pillar is in a range from 1:2 to 1:5.

19. The semiconductor package of claim 18, wherein the first film comprises tin.

20. The semiconductor package of claim 18, wherein a third chip is arranged on the fourth redistribution structure.
